(19) United States
(12) Patent Application Publication
(10) Pub. No.: US 2014/0206185 A1
(43) Pub. Date: Jul. 24, 2014

(54) BALL PLACEMENT IN A PHOTO-PATTERNED TEMPLATE FOR FINE PITCH INTERCONNECT

(71) Applicants: Ming Lei, Chandler, AZ (US); Edward A. Zarbock, Gilbert, AZ (US)

(72) Inventors: Ming Lei, Chandler, AZ (US); Edward A. Zarbock, Gilbert, AZ (US)

(21) Appl. No.: 13/976,006

(22) PCT Filed: Dec. 21, 2011
(86) PCT No.: PCT/US11/66655

§ 371 Date: Jun. 25, 2013

(51) Int. Cl. H01L 23/00

(52) U.S. Cl. CPC H01L 24/11
USPC 438/613

(57) ABSTRACT

A photo-patternable polymer film is deposited on a substrate, wherein the substrate includes metal pads. Ultraviolet light is transmitted through a photomask on the deposited photopatternable polymer film to generate cavities in Depositing a film on a substrate, wherein the substrate includes metal pads the deposited polymer film and expose the metal pads. The substrate is developed and rinsed, and then flux is applied on the surface of the substrate. Balls are placed in the generated cavities. A reflow process is performed to form bumps and remove flux, subsequent to the placing of the balls in the generated cavities. Plasma cleaning is performed to remove the photo-patternable film.

### BACKGROUND

1. Field

The disclosure relates to a method for ball placement in a photo-patterned template for fine pitch interconnect.

2. Background

Integrated circuits may be formed on semiconductor wafers made from materials such as silicon. The semiconductor wafers are processed to form various electronic devices. The wafers are diced into semiconductor chips (a chip is also known as a die), which may then be attached to a package substrate using a variety of known methods. In one known method for attaching a chip or die to a package substrate, the die may have solder bump contacts which are electrically coupled to the integrated circuit. The solder bump contacts extend onto the contact pads of a package substrate, and are typically attached in a thermal reflow process. Electronic signals may be provided through the solder bump contacts to and from the integrated circuit on the die.

Surface mount technology is a mechanism for constructing electronic circuits in which components are mounted directly onto the surface of printed circuit boards (PCBs). A ball grid array (BGA) is a type of surface mount packaging that is used for integrated circuits. Balls of solder are first soldered to the pads on the surface mount package. These balls of solder may conduct electrical signals from the integrated circuit to the printed circuit board (PCB) on which the BGA is placed. The solder spheres may be held in place with flux until soldering occurs. The device may be placed on a PCB with copper pads in a pattern that matches the solder balls. The assembly may then be heated, either in a reflow oven or via an infrared heater, causing the solder balls to melt. Surface tension causes the molten solder to hold the package in alignment with a circuit board, at a correct separation distance, while the solder cools and solidifies. In certain situations, BGA balls are soldered to the pads on the surface mount package and shipped to a customer who then solders the BGA balls to the PCB.

A second level interconnect (SLI) is the interconnect made by the attachment of a device or a component to a PCB. Ball attach process for BGA package is becoming more and more challenging as the SLI pitch becomes smaller, and as substrates become thinner. Solder ball bridging and missing are some of the top contributors for yield loss. As SLI pitch shrinks, flux print and ball placements may require a very high accuracy in the ball attach process. Substrate warpage also increases flux print variations and causes ball placement offset. In certain situations, even +3 to 4 mil warpage may cause a 5-10% yield loss on thin packages. Such warpage level may be common on thin-core or coreless substrates.

Bumpless build-up layer (BBUL) is a processor packaging technology that does not use the usual tiny solder bumps to attach the silicon die to the processor package wires. BBUL is bumpless, because BBUL does not use the usual tiny solder bumps to attach the silicon die to the processor package wires. BBUL has build-up layers, because BBUL is grown or built up around the silicon die. BBUL differs from traditional assembled packages in that BBUL uses a die or dice embedded in a substrate, such as bismaleimide triazine (BT) laminate or a copper heat spreader, which then has one or more build-up layers. Microvia formation processes, such as laser drilling may make the connections between the build-up layers and the die bond pads.

### BRIEF DESCRIPTION OF THE DRAWINGS

Referring now to the drawings in which like reference numbers represent corresponding parts throughout:

FIG. 1 illustrates a block diagram that shows how a polymer film is applied on substrate panels via lamination, in accordance with certain embodiments;

FIG. 2 illustrates a block diagram that shows how screen printing is performed, in accordance with certain embodiments;

FIG. 3 illustrates a block diagram that shows how patterning is performed to expose metal pads, in accordance with certain embodiments;

FIG. 4 illustrates a block diagram that shows how a low-viscosity no-clean flux is sprayed on a substrate, in accordance with certain embodiments;

FIG. 5 illustrates a block diagram that shows how balls are placed in cavities, in accordance with certain embodiments;

FIG. 6 illustrates a block diagram that shows how a reflow process is used to form bumps and remove lumps, in accordance with certain embodiments;

FIG. 7 illustrates a block diagram that shows how plasma cleaning is performed to remove polymer film, in accordance with certain embodiments; and

FIG. 8 illustrates a flowchart that shows certain operations, in accordance with certain embodiments.

### DETAILED DESCRIPTION

In the following description, reference is made to the accompanying drawings which form a part hereof and which illustrate several embodiments. It is understood that other embodiments may be utilized and structural and operational changes may be made.

Certain embodiments apply a photo patternable polymer film on a substrate and use equipment and processes to enable fine pitch (e.g., a pitch less than 0.4 mm) ball attach on BGA packages and BBUL. In certain exemplary embodiments, a photo-patternable polymer film is deposited on a substrate. Ultraviolet light is transmitted through a photomask on the deposited photo-patternable polymer film to generate cavities in the deposited polymer film and expose metal pads contained in the substrate. The substrate is developed and rinsed, and then flux is applied on the surface of the substrate. Balls are placed in the generated cavities. A reflow process is performed to form bumps and remove flux, subsequent to the placing of the balls in the generated cavities. Plasma cleaning is performed to remove the photo-patternable polymer film.

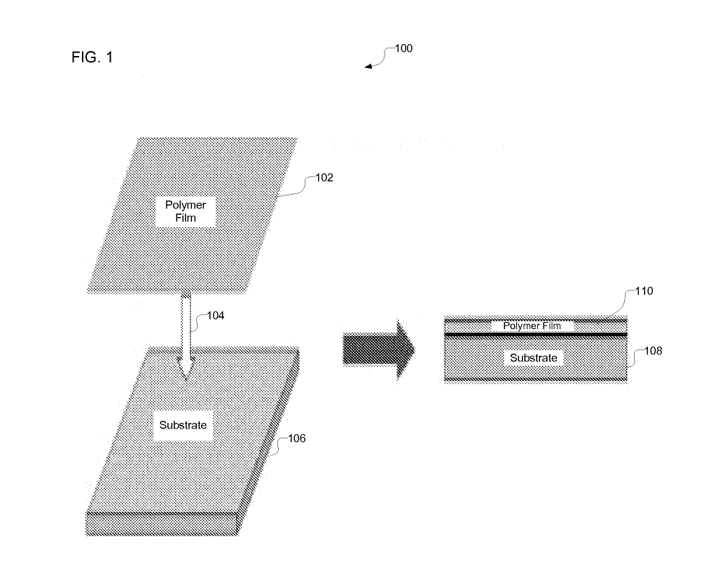

FIG. 1 illustrates a block diagram 100 that shows how a polymer film 102 is applied (reference numeral 104) on an exemplary substrate panel 106 via lamination, in accordance with certain embodiments. During the lamination process, the polymer film is applied on substrate panels with pressure and heat. A side view of an exemplary substrate panel 108 coated with an exemplary polymer film 110 that is generated after the lamination process is shown in FIG. 1. The polymer film is photo-patternable, i.e., patterns may be etched on the polymer film by certain frequencies of light applied at certain intensities on the polymer film. The polymer film that is used is able to survive a high temperature assembly process of up to 250 degree Celsius. For example, in certain embodiments the polymer film has a melting point greater than 250 degree Celsius.

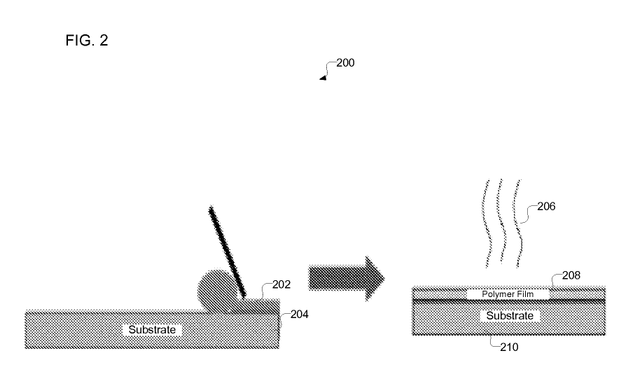

FIG. 2 illustrates a block diagram 200 that shows how screen printing is performed to apply a polymer film over an exemplary substrate panel, in accordance with certain embodiments. Screen printing is used in certain embodiments instead of the lamination process to apply the polymer film over the exemplary substrate panel.

In screen printing, a liquid 202 is printed on a substrate panel 204. The substrate panel with the printed liquid is soft baked to evaporate (reference numeral 206) the solvent from the liquid and leave an exemplary polymer film 208 deposited on an exemplary substrate panel 210. The soft baking may comprise heating the printed liquid.

In alternative embodiments, other mechanisms besides lamination or screen printing may be used to apply a photo-patternable polymer film on a substrate panel.

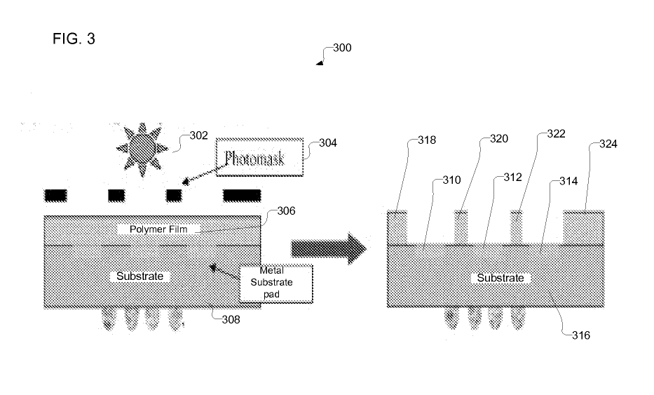

FIG. 3 illustrates a block diagram 300 that shows how patterning is performed to expose metal substrate pads made out of copper, in accordance with certain embodiments. An ultraviolet radiation source 302 generates ultraviolet radiation that is made to pass through a photomask 304. The photomask 304 is an opaque plate with holes that allows ultraviolet radiation to pass through the holes in a defined pattern.

The ultraviolet radiation falls on the photo-patternable polymer film 306 that has been applied on the substrate 308. The ultraviolet radiation etches the photo-patternable polymer film 306 to expose metal substrate pads 310, 312, 314 that reside on the substrate 316. The etching is in accordance with the hole patterns of the photomask 304. Reference numerals 318, 320, 322, 324 show remaining portions of the photo-patternable polymer film 306 after the photo-patternable polymer film 306 is etched with the ultraviolet radiation.

The usage of the photomask allows the exposure of the metal substrate pads that are closely spaced with barriers 318, 320, 322, 324 separating the exposed metal substrate pads. The substrate with the metal substrate pads and the photo-patternable polymer film are then developed and rinsed.

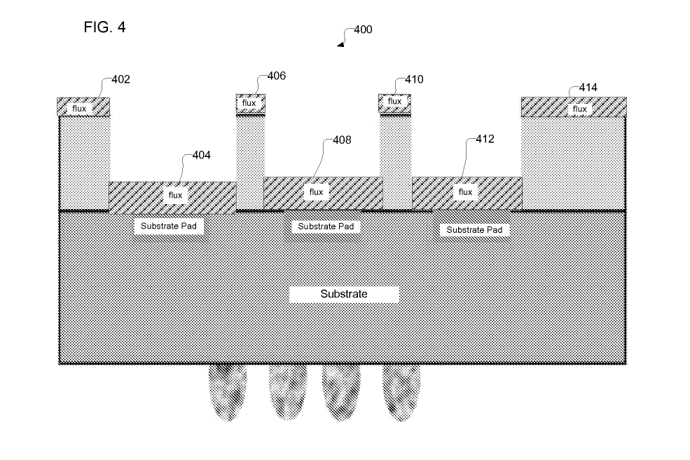

FIG. 4 illustrates a block diagram 400 that shows how a low-viscosity no-clean flux 402, 404, 406, 408, 410, 412, 414 is sprayed on a substrate, in accordance with certain embodiments. In certain embodiment, the low-viscosity no-clean flux 402 may be applied on the substrate through one or more processes that are different from spraying.

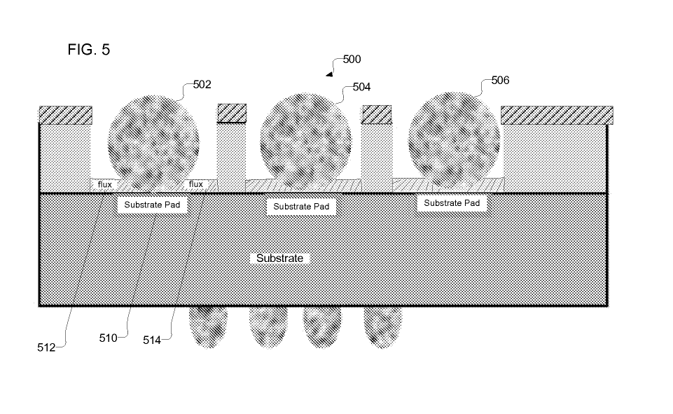

FIG. 5 illustrates a block diagram 500 that shows how solder balls 502, 504, 506 are placed in cavities, in accordance with certain embodiments. In certain embodiments, the solder balls 502, 504, 506 are placed in the cavities formed by the patterned template film and on the substrate pads on which the low-viscosity no-clean flux has been sprayed. For example, the solder ball 502 has been placed in contact with the substrate pad 510, and the solder ball 502 is embedded in the flux 512, 514.

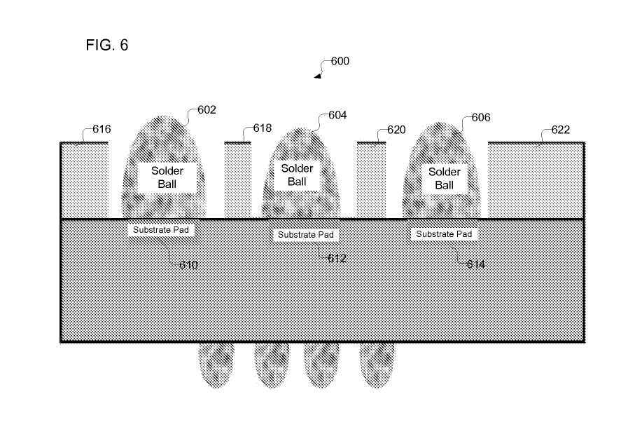

FIG. 6 illustrates a block diagram 600 that shows how a reflow process is used to form bumps and remove lumps, in accordance with certain embodiments. After reflow, solder balls 602, 604, 606 are formed on substrate pads 610, 612, 614. With the segregation of the polymer template, fine pitch (i.e., pitch of less than 4 mm) ball attach can be enabled, even on high warpage substrates Solder ball bridging and missing balls can be significantly reduced with the use of the polymer template. In FIG. 6 the remaining polymer film is shown via reference numerals 616, 618, 620, 622.

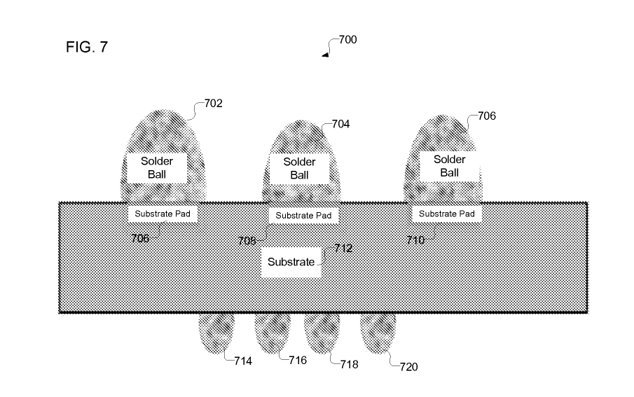

FIG. 7 illustrates a block diagram 700 that shows how plasma cleaning is performed to remove polymer film, in accordance with certain embodiments. After ball attach the polymer film 616, 618, 620, 622 can be removed via etching with plasma cleaning. In FIG. 7 solder balls 702, 704, 706 are shown in contact with substrate pads 706, 708, 710 that are on the substrate 712. Also shown are first level interconnect solders 714, 716, 718, 720.

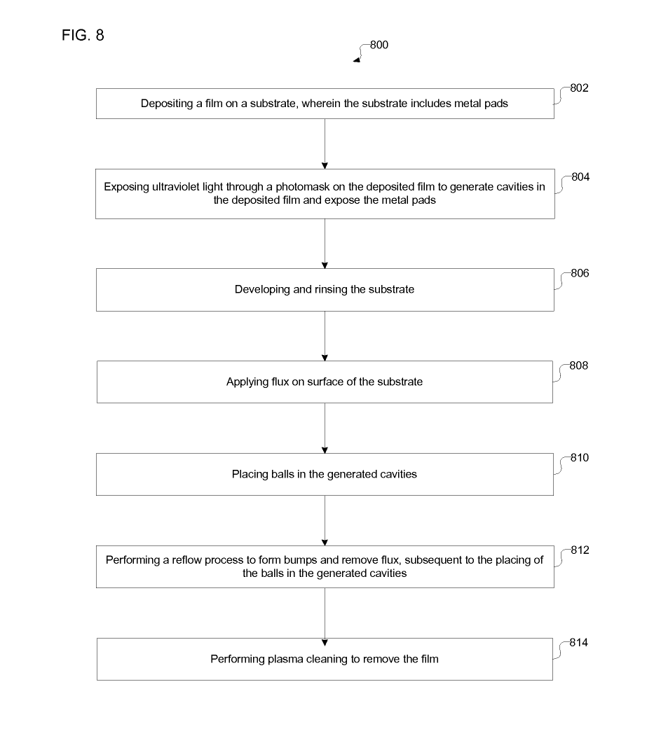

FIG. 8 illustrates a flowchart 800 that shows certain operations, in accordance with certain embodiments. A photo-patternable polymer film is deposited (at block 802) on a substrate, wherein the substrate includes metal pads. Ultraviolet light is transmitted (at block 804) through a photomask on the deposited photo-patternable polymer film to generate cavities in the deposited polymer film and expose the metal pads. The substrate is developed and rinsed (at block 806), and then flux is applied (at block 808) on the surface of the substrate. Balls are placed (at block 810) in the generated cavities. A reflow process is performed (at block 812) to form bumps and remove flux, subsequent to the placing of the balls in the generated cavities. Plasma cleaning is performed (at block 814) to remove the photo-patternable film.

Therefore, FIGS. 1-8 show certain embodiments in which balls are placed at a fine pitch within cavities generated on a photo-patternable polymer film by transmitting ultraviolet light though a photomask. The balls contact metallic substrate pads that are contained in the substrate.

The embodiments shown in FIGS. 1-8 can use BGA, or alternatively bumpless build-up Layer or BBUL may be used instead of the BGA. BBUL is a processor packaging technology that does not use the usual tiny solder bumps to attach the silicon die to the processor package wires but uses build-up layers. In BBUL, the photo-patterned template can be used prior to solder bumping. BBUL solder ball attach may assist in the reducing of BBUL warpage.

The components shown or referred to in FIGS. 1-8 are described as performing specific types of operations. In alternative embodiments, the structures components may be structured differently and have fewer, more or different functions than those shown or referred to in the figures.

Therefore, the foregoing description of the embodiments has been presented for the purposes of illustration and description. It is not intended to be exhaustive or to limit the embodiments to the precise form disclosed. Many modifications and variations are possible in light of the above teaching.

What is claimed is:

1. A method, comprising:
depositing a film on a substrate, the substrate including metal pads;
transmitting ultraviolet light through a photomask on the deposited film to generate cavities in the deposited film and expose the metal pads; and
placing balls in the generated cavities.

2. The method of claim 1, the method further comprising:
applying flux on surface of the substrate, prior to the placing of the balls in the generated cavities.

3. The method of claim 2, the method further comprising:
performing a reflow process to form bumps and remove flux, subsequent to the placing of the balls in the generated cavities; and
performing plasma cleaning to remove the film.

4. The method of claim 2, the method further comprising:
developing and rinsing the substrate, prior to the applying of the flux.

5. The method of claim 1, wherein the film is a photo-patternable polymer film, and wherein the depositing further comprises:
applying the photo-patternable polymer film with pressure and heat on the substrate.

6. The method of claim 1, wherein the film is a photo-patternable polymer film, and wherein the depositing further comprises:
applying a liquid on the substrate via screen printing; and
heating the applied liquid to evaporate solvent and leave the photo-patternable polymer film on the substrate.

7. The method of claim 1, wherein the film has a melting point greater than 250 degree Celsius.

8. The method of claim 1, wherein the substrate is a ball grid array substrate.

9. The method of claim 1, wherein the substrate is a bumpless build-up layer substrate.

10. A method, comprising:
depositing a polymer film on a substrate, the substrate including metal pads;
transmitting ultraviolet light through a photomask on the deposited polymer film to generate cavities in the deposited polymer film and expose the metal pads;
developing and rinsing the substrate;
applying flux on surface of the substrate; and
placing balls in the generated cavities.

11. The method of claim 10, the method further comprising:
performing a reflow process to form bumps and remove flux, subsequent to the placing of the balls in the generated cavities; and
performing plasma cleaning to remove the film.

12. The method of claim 10, wherein the polymer film is photo-patternable, and wherein the depositing further comprises:
applying the polymer film with pressure and heat on the substrate.

13. The method of claim 10, wherein the polymer film is photo-patternable, and wherein the depositing further comprises:
applying a liquid on the substrate via screen printing; and
heating the applied liquid to evaporate solvent and leave the polymer film on the substrate.

14. The method of claim 10, wherein the film has a melting point greater than 250 degree Celsius.

15. The method of claim 10, wherein the substrate is a ball grid array substrate.

16. The method of claim 10, wherein the substrate is a bumpless build-up layer substrate.

17. A method, comprising:
depositing a photo-patternable polymer film on a substrate, the substrate including metal pads;
transmitting ultraviolet light through a photomask on the deposited photo-patternable polymer film to generate cavities in the deposited photo-patternable polymer film and expose the metal pads;
developing and rinsing the substrate;
applying flux on surface of the substrate;
placing balls in the generated cavities;
performing a reflow process to form bumps and remove flux, subsequent to the placing of the balls in the generated cavities; and
performing plasma cleaning to remove the photo-patternable polymer film.

18. The method of claim 17, wherein the depositing further comprises:
applying the photo-patternable polymer film with pressure and heat on the substrate.

19. The method of claim 18, wherein the film has a melting point greater than 250 degree Celsius, and wherein the substrate is a ball grid array substrate.

20. The method of claim 17, wherein the depositing further comprises:
applying a liquid on the substrate via screen printing; and
heating the applied liquid to evaporate solvent and leave the photo-patternable polymer film on the substrate.
